(19) United States
(12) Patent Application Publication
(10) Pub. No.: US 2026/0090053 A1
(43) Pub. Date: Mar. 26, 2026

(54) SEMICONDUCTOR MEMORY DEVICE

(71) Applicant: Kioxia Corporation, Tokyo (JP)

(72) Inventors: Tsunehiro INO, Fujisawa (JP); Masamichi SUZUKI, Koto (JP)

(73) Assignee: Kioxia Corporation, Tokyo (JP)

(21) Appl. No.: 19/065,298

(22) Filed: Feb. 27, 2025

(30) Foreign Application Priority Data
Sep. 20, 2024 (JP) 2024-164010

(51) Int. Cl. H10D 64/01; G11C 16/04; H10B 43/10; H10B 43/27; H10B 43/35

(52) U.S. Cl. CPC H10D 64/037; G11C 16/0483; H10B 43/10; H10B 43/27; H10B 43/35

(57) ABSTRACT

A semiconductor memory device of embodiments includes: a semiconductor layer; a gate electrode layer; a first insulating layer between the semiconductor layer and the gate electrode layer; a second insulating layer between the first insulating layer and the gate electrode layer; and a charge storage layer between the first insulating layer and the second insulating layer, containing at least one first crystal including a first region having one space group selected from a group consisting of a space group Pca21 (space group number 29), a space group R3 (space group number 146), a space group R3m (space group number 160), and a space group Pmn21 (space group number 31), and containing at least one first element selected from a group consisting of Hf and Zr, at least one second element selected from a group consisting of Ti, Ce, Ta, W, Nb, Mo, Mn, Ru, and Sn, and oxygen.

### CROSS-REFERENCE TO RELATED APPLICATION

This application is based upon and claims the benefit of priority from Japanese Patent Application No. 2024-164010, filed on Sep. 20, 2024, the entire contents of which are incorporated herein by reference.

### FIELD

Embodiments described herein relate generally to a semiconductor memory device.

### BACKGROUND

In flash memories, it is desirable to make the charge storage layer thinner in order to scale down memory cells. In order to make the charge storage layer thinner, it is necessary to improve the charge storage capacity per unit thickness of the charge storage layer.

### BRIEF DESCRIPTION OF THE DRAWINGS

FIG. 1 is a schematic cross-sectional view of a semiconductor memory device according to a first embodiment;

FIG. 2 is a schematic cross-sectional view of a part of a charge storage layer according to the first embodiment;

FIG. 3 is an explanatory diagram of the function and effect of the semiconductor memory device according to the first embodiment;

FIG. 4 is a schematic cross-sectional view of a part of a charge storage layer according to a second embodiment;

FIG. 5 is an explanatory diagram of the function and effect of a semiconductor memory device according to the second embodiment;

FIG. 6 is a schematic cross-sectional view of a part of a charge storage layer according to a third embodiment;

FIG. 7 is an explanatory diagram of the function and effect of a semiconductor memory device according to the third embodiment;

FIG. 8 is a schematic cross-sectional view of a part of a charge storage layer according to a fourth embodiment;

FIG. 9 is an explanatory diagram of the function and effect of a semiconductor memory device according to the fourth embodiment;

FIG. 10 is a circuit diagram of a memory cell array in a semiconductor memory device according to a fifth embodiment; and

FIGS. 11A and 11B are schematic cross-sectional views of a memory cell array in the semiconductor memory device according to the fifth embodiment.

### DETAILED DESCRIPTION

A semiconductor memory device of embodiments includes: a semiconductor layer; a gate electrode layer; a first insulating layer provided between the semiconductor layer and the gate electrode layer; a second insulating layer provided between the first insulating layer and the gate electrode layer; and a charge storage layer provided between the first insulating layer and the second insulating layer, the charge storage layer including at least one first crystal including a first region having one space group selected from a group consisting of a space group Pca21 (space group number 29), a space group R3 (space group number 146), a space group R3m (space group number 160), and a space group Pmn21 (space group number 31), and the charge storage layer containing oxygen (O), at least one first element selected from a group consisting of hafnium (Hf) and zirconium (Zr), and at least one second element selected from a group consisting of titanium (Ti), cerium (Ce), tantalum (Ta), tungsten (W), niobium (Nb), molybdenum (Mo), manganese (Mn), ruthenium (Ru), and tin (Sn).

Hereinafter, embodiments will be described with reference to the diagrams. In addition, in the following description, the same or similar members and the like are denoted by the same reference numerals, and the description of the members and the like once described will be omitted as appropriate.

In addition, in this specification, the term “upper” or “lower” may be used for convenience. “Upper” or “lower” is a term indicating the relative positional relationship in the diagram, but is not a term that defines the positional relationship with respect to gravity.

The qualitative analysis and quantitative analysis of the chemical composition of members forming the semiconductor memory device in this specification can be performed by, for example, secondary ion mass spectroscopy (SIMS), energy dispersive X-ray spectroscopy (EDX), or electron energy loss spectroscopy (EELS). In addition, when measuring the thickness of each member forming the semiconductor memory device, a distance between members, and the like, for example, a transmission electron microscope (TEM) can be used. In addition, for the identification of the crystal system of each member forming the semiconductor memory device and the comparison of the abundance ratio of the crystal systems, for example, a scanning transmission electron microscope (STEM), X-ray diffraction (XRD), electron beam diffraction (EBD), X-ray photoelectron spectroscopy (XPS), or synchrotron radiation X-ray absorption fine structure (XAFS) can be used. In addition, the presence or absence of an oriented texture in the members forming the semiconductor memory device can be checked by using, for example, a TEM. In addition, the presence of polarization domains in the crystals forming the semiconductor memory device can be checked and the polarization direction of the polarization domains can be specified by using, for example, a Cs-corrected Scanning Transmission Electron Microscope (Cs-corrected STEM).

### First Embodiment

A semiconductor memory device according to a first embodiment includes: a semiconductor layer; a gate electrode layer; a first insulating layer provided between the semiconductor layer and the gate electrode layer; a second insulating layer provided between the first insulating layer and the gate electrode layer; and a charge storage layer provided between the first insulating layer and the second insulating layer, containing at least one first crystal including a first region having one space group selected from a group consisting of a space group Pca21 (space group number 29), a space group R3 (space group number 146), a space group R3m (space group number 160), and a space group Pmn21 (space group number 31), and containing at least one first element selected from a group consisting of hafnium (Hf) and zirconium (Zr), at least one second element selected from a group consisting of titanium (Ti), cerium (Ce), tantalum (Ta), tungsten (W), niobium (Nb), molybdenum (Mo), manganese (Mn), ruthenium (Ru), and tin (Sn), and oxygen (O).

The first crystal of the semiconductor memory device according to the first embodiment further includes a second region including one space group selected from a group consisting of a space group P42/nmc (space group number 137), a space group Pbca (space group number 61), and a space group Pbcm (space group number 57).

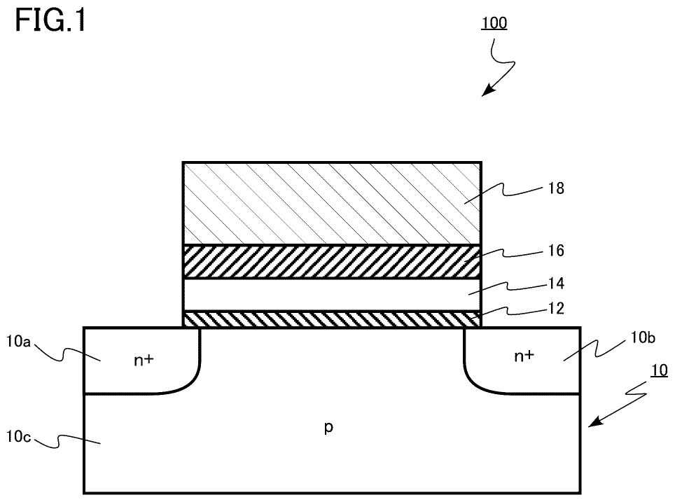

FIG. 1 is a schematic cross-sectional view of the semiconductor memory device according to the first embodiment. The semiconductor memory device according to the first embodiment is a charge trap type memory cell 100 that traps charges in a charge storage layer.

The memory cell 100 according to the first embodiment includes a semiconductor layer 10, a tunnel insulating layer 12, a charge storage layer 14, a block insulating layer 16, and a gate electrode layer 18. The tunnel insulating layer 12 is an example of the first insulating layer. The block insulating layer 16 is an example of the second insulating layer. The semiconductor layer 10 has a source region 10a, a drain region 10b, and a channel region 10c.

The semiconductor layer 10 is, for example, single crystal silicon.

The source region 10a is provided in the semiconductor layer 10. The source region 10a is, for example, an n-type impurity region. The drain region 10b is provided in the semiconductor layer 10. The drain region 10b is, for example, an n-type impurity region. The channel region 10c is provided in the semiconductor layer 10. The channel region 10c is, for example, a p-type impurity region.

The tunnel insulating layer 12 is provided on the semiconductor layer 10. The tunnel insulating layer 12 is provided between the semiconductor layer 10 and the gate electrode layer 18.

The tunnel insulating layer 12 has a function of allowing charges to pass therethrough according to the voltage applied between the gate electrode layer 18 and the semiconductor layer 10.

The tunnel insulating layer 12 is, for example, an oxide, an oxynitride, or a nitride. The tunnel insulating layer 12 contains, for example, silicon oxide, silicon oxynitride, or silicon nitride. The thickness of the tunnel insulating layer 12 in a direction from the semiconductor layer 10 toward the gate electrode layer 18 is, for example, equal to or more than 3 nm and equal to or less than 8 nm.

The charge storage layer 14 is provided on the tunnel insulating layer 12. The charge storage layer 14 is disposed between tunnel insulating layer 12 and block insulating layer 16. The thickness of the charge storage layer 14 in a direction from the semiconductor layer 10 toward the gate electrode layer 18 is, for example, equal to or more than 2 nm and equal to or less than 10 nm.

The charge storage layer 14 has a function of trapping and storing charges. The charge is, for example, an electron. The threshold voltage of the transistor of the memory cell 100 changes according to the amount of charges stored in the charge storage layer 14. By using the threshold voltage change, the memory cell 100 can store data.

For example, when the threshold voltage of the transistor of the memory cell 100 changes, the voltage at which the transistor of the memory cell 100 is turned on changes. For example, if a state in which the threshold voltage is high is defined as data “0” and a state in which the threshold voltage is low is defined as data “1”, the memory cell can store 1-bit data of “0” and “1”.

The charge storage layer 14 contains at least one first element selected from a group consisting of hafnium (Hf) and zirconium (Zr) and at least one second element selected from a group consisting of titanium (Ti), cerium (Ce), tantalum (Ta), tungsten (W), niobium (Nb), molybdenum (Mo), manganese (Mn), ruthenium (Ru), and tin (Sn), and oxygen (O).

The charge storage layer 14 is, for example, a hafnium oxide or a zirconium oxide. The charge storage layer 14 is, for example, a hafnium oxide containing zirconium (Zr). The charge storage layer 14 is, for example, a zirconium oxide containing hafnium (Hf).

The charge storage layer 14 contains, for example, hafnium oxide or zirconium oxide as a main component. The charge storage layer 14 is, for example, a hafnium oxide layer or a zirconium oxide layer.

The charge storage layer 14 contains, for example, hafnium oxide as a main component. The term “containing hafnium oxide as a main component” means that the proportion of hafnium oxide among the components contained in the charge storage layer 14 is the highest.

Among the elements contained in the charge storage layer 14, the atomic ratio of hafnium (Hf) and oxygen (O) is, for example, equal to or more than 85%.

Among the elements contained in the charge storage layer 14, the atomic ratio of hafnium (Hf), zirconium (Zr), and oxygen (O) is, for example, equal to or more than 85%.

The charge storage layer 14 contains, for example, zirconium oxide as a main component. The term “containing zirconium oxide as a main component” means the proportion of zirconium oxide among the components contained in the charge storage layer 14 is the highest.

Among the elements contained in the charge storage layer 14, the atomic ratio of zirconium (Zr) and oxygen (O) is, for example, equal to or more than 85%.

Among the elements contained in the charge storage layer 14, the atomic ratio of zirconium (Zr), hafnium (Hf), and oxygen (O) is, for example, equal to or more than 85%.

The charge storage layer 14 contains at least one second element selected from a group consisting of titanium (Ti), cerium (Ce), tantalum (Ta), tungsten (W), niobium (Nb), molybdenum (Mo), manganese (Mn), ruthenium (Ru), and tin (Sn). The ratio of the atomic concentration of the second element to the atomic concentration of the first element in the charge storage layer 14 is, for example, equal to or more than 1% and equal to or less than 15%.

The charge storage layer 14 contains, for example, at least one third element selected from a group consisting of barium (Ba), strontium (Sr), and calcium (Ca). The atomic concentration of the third element contained in the charge storage layer 14 is lower than, for example, the atomic concentration of the second element contained in the charge storage layer 14.

The charge storage layer 14 contains, for example, at least one fourth element selected from a group consisting of aluminum (Al) and silicon (Si), for example. The atomic concentration of the fourth element contained in the charge storage layer 14 is lower than, for example, the atomic concentration of the second element contained in the charge storage layer 14.

The charge storage layer 14 contains, for example, the third element and the fourth element.

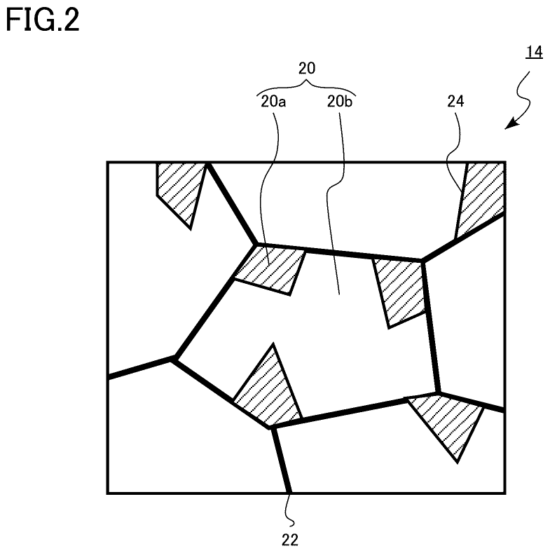

FIG. 2 is a schematic cross-sectional view of a part of the charge storage layer according to the first embodiment. FIG. 2 is a cross section parallel to a direction from the semiconductor layer 10 toward the gate electrode layer 18. In other words, FIG. 2 is a cross section perpendicular to the surface of the semiconductor layer 10.

The charge storage layer 14 is polycrystalline. The charge storage layer 14 contains a plurality of crystal grains 20. There is a grain boundary 22 between the crystal grains 20 adjacent to each other. Each of the plurality of crystal grains 20 is an example of the first crystal.

The crystal grain 20 contains: at least one first element selected from a group consisting of hafnium (Hf) and zirconium (Zr); at least one second element selected from a group consisting of titanium (Ti), cerium (Ce), tantalum (Ta), tungsten (W), niobium (Nb), molybdenum (Mo), manganese (Mn), ruthenium (Ru), and tin (Sn); and oxygen (O).

The crystal grain 20 is, for example, a hafnium oxide or a zirconium oxide. The charge storage layer 14 is, for example, a hafnium oxide containing zirconium (Zr). The charge storage layer 14 is, for example, a zirconium oxide containing hafnium (Hf).

The crystal grain 20 contains, for example, hafnium oxide or zirconium oxide as a main component.

The crystal grain 20 contains, for example, hafnium oxide as a main component. Among the elements contained in the crystal grain 20, the atomic ratio of hafnium (Hf) and oxygen (O) is, for example, equal to or more than 90%. Among the elements contained in the crystal grain 20, the atomic ratio of hafnium (Hf), zirconium (Zr), and oxygen (O) is, for example, equal to or more than 90%.

The crystal grain 20 contains, for example, zirconium oxide as a main component. Among the elements contained in the crystal grain 20, the atomic ratio of zirconium (Zr) and oxygen (O) is, for example, equal to or more than 90%. Among the elements contained in the crystal grain 20, the atomic ratio of zirconium (Zr), hafnium (Hf), and oxygen (O) is, for example, equal to or more than 90%.

The crystal grain 20 contains at least one second element selected from a group consisting of titanium (Ti), cerium (Ce), tantalum (Ta), tungsten (W), niobium (Nb), molybdenum (Mo), manganese (Mn), ruthenium (Ru), and tin (Sn). The ratio of the atomic concentration of the second element to the atomic concentration of the first element in the crystal grain 20 is, for example, equal to or more than 1% and equal to or less than 9%.

The crystal grain 20 contains, for example, at least one third element selected from a group consisting of barium (Ba), strontium (Sr), and calcium (Ca). The atomic concentration of the third element contained in the crystal grain 20 is lower than, for example, the atomic concentration of the second element contained in the crystal grain 20.

For example, the atomic concentration of the fourth element contained in the crystal grain 20 containing at least one fourth element selected from a group consisting of aluminum (Al) and silicon (Si) is lower than the atomic concentration of the second element contained in the crystal grain 20.

The crystal grain 20 contains, for example, the third element and the fourth element.

The median of the long diameters of the crystal grains 20 is, for example, equal to or more than 1 nm and equal to or less than 5 nm. The median of the long diameters of the crystal grains 20 is, for example, equal to or more than one-twentieth and equal to or less than one-half the thickness of the charge storage layer 14 in a direction from the semiconductor layer 10 toward the gate electrode layer 18. For example, the long diameters of ten crystal grains 20 randomly selected in a cross-sectional image acquired by TEM can be measured, and the median of the long diameters of the crystal grains 20 can be calculated.

The crystal grain 20 includes a first polarization domain 20a and a second polarization domain 20b. The crystal grain 20 includes, for example, a plurality of first polarization domains 20a and a plurality of second polarization domains 20b. There is a domain wall 24 between the first polarization domain 20a and the second polarization domain 20b adjacent to each other.

The first polarization domain 20a is an example of the first region. The second polarization domain 20b is an example of the second region. The first polarization domain 20a and the second polarization domain 20b are examples of a polarization domain.

The crystal grains 20 include, for example, a plurality of first polarization domains 20a. The median of the number of first polarization domains 20a included in each of the plurality of crystal grains 20 is equal to or more than 3 and equal to or less than 100. For example, the number of first polarization domains 20a included in each of ten crystal grains 20 randomly selected in a cross-sectional image acquired by STEM can be measured, and the median of the number of first polarization domains 20a can be calculated.

The first polarization domain 20a has one space group selected from a group consisting of a space group Pca21 (space group number 29), a space group R3 (space group number 146), a space group R3m (space group number 160), and a space group Pmn21 (space group number 31). A hafnium oxide or a zirconium oxide having the space group Pca21 (space group number 29), the space group R3 (space group number 146), the space group R3m (space group number 160), or the space group Pmn21 (space group number 31) is a ferroelectric. The first polarization domain 20a has ferroelectric properties.

The second polarization domain 20b has one space group selected from a group consisting of a space group P42/nmc (space group number 137), a space group Pbca (space group number 61), and a space group Pbcm (space group number 57). A hafnium oxide or a zirconium oxide having the space group P42/nmc (space group number 137), the space group Pbca (space group number 61), or the space group Pbcm (space group number 57) is an antiferroelectric. The second polarization domain 20b has antiferroelectric properties.

The block insulating layer 16 is provided between the tunnel insulating layer 12 and the gate electrode layer 18. The block insulating layer 16 is provided between the charge storage layer 14 and the gate electrode layer 18.

The block insulating layer 16 has a function of blocking a current flowing between the charge storage layer 14 and the gate electrode layer 18.

The block insulating layer 16 is, for example, an oxide, an oxynitride, or a nitride. The block insulating layer 16 contains, for example, silicon oxide or aluminum oxide.

The gate electrode layer 18 is a metal or a semiconductor. The gate electrode layer 18 is, for example, polycrystalline silicon containing n-type impurities or p-type impurities.

For example, a NAND string of a NAND flash memory can be formed by connecting the memory cells 100 shown in FIG. 1 in series.

Next, an example of a method for manufacturing the semiconductor memory device according to the first embodiment will be described. Hereinafter, a case where the charge storage layer 14 is a hafnium oxide layer will be described as an example.

First, a silicon oxide film is formed on a silicon substrate using a thermal oxidation method. The silicon substrate becomes the semiconductor layer 10. The silicon oxide film becomes the tunnel insulating layer 12.

Then, a hafnium oxide film containing at least one second element selected from a group consisting of titanium (Ti), cerium (Ce), tantalum (Ta), tungsten (W), niobium (Nb), molybdenum (Mo), manganese (Mn), ruthenium (Ru), and tin (Sn) is formed on the silicon oxide film using an atomic layer deposition method (ALD method). When forming the hafnium oxide film, the amount of oxygen contained in the hafnium oxide film is shifted from the stoichiometric ratio, thereby applying a tensile stress to the hafnium oxide film. In addition, when the hafnium oxide film is formed, a silicon nitride film, a titanium oxide film or a cerium oxide film that functions as a stress application film is provided so as to be in contact with the hafnium oxide film. The hafnium oxide film becomes the charge storage layer 14.

In addition, when forming a hafnium oxide film using the ALD method, at least one third element selected from a group consisting of barium (Ba), strontium (Sr), and calcium (Ca) or at least one fourth element selected from a group consisting of aluminum (Al) and silicon (Si) can also be contained in the hafnium oxide film.

Then, a silicon oxide film is formed on the charge storage layer 14. The silicon oxide film is formed by using, for example, a chemical vapor deposition method (CVD method). The silicon oxide film becomes the block insulating layer 16.

Then, a polycrystalline silicon film containing conductive impurities is formed. The polycrystalline silicon film is formed by using, for example, a CVD method. The polycrystalline silicon film becomes the gate electrode layer 18.

Then, the polycrystalline silicon film, the silicon oxide film, the hafnium oxide film, and the silicon oxide film are patterned to form a gate electrode structure.

Then, impurity ions are implanted into the silicon substrate and activation annealing is performed to form the source region 10a and the drain region 10b.

Next, the function and effect of the semiconductor memory device according to the first embodiment will be described.

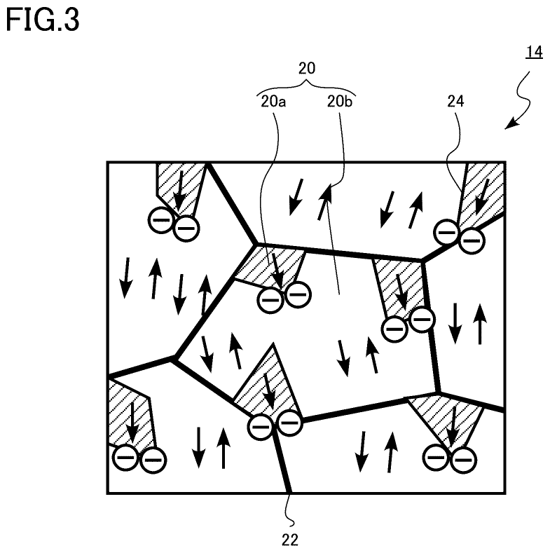

FIG. 3 is an explanatory diagram of the function and effect of the semiconductor memory device according to the first embodiment. FIG. 3 is a schematic cross-sectional view of a part of the charge storage layer according to the first embodiment. FIG. 3 is a diagram corresponding to FIG. 2. In addition, the arrows in FIG. 3 indicate the polarization direction of each polarization domain.

FIG. 3 is a diagram showing a state in which a write voltage is applied between the semiconductor layer 10 and the gate electrode layer 18 to store electrons in the charge storage layer 14. When electrons are stored in the charge storage layer 14, for example, a gate voltage that is positive with respect to the semiconductor layer 10 is applied to the gate electrode layer 18, thereby injecting electrons from the semiconductor layer 10 into the charge storage layer 14.

A plurality of first polarization domains 20a exist in the crystal grain 20. The first polarization domain 20a has ferroelectric properties, and is polarized by the application of the gate voltage so that the semiconductor layer 10 side is positive and the gate electrode layer 18 side is negative.

As shown in FIG. 3, the electrons injected into the charge storage layer 14 are trapped by the domain wall 24 on the semiconductor layer 10 side of the first polarization domain 20a, and the electrons are stored in the charge storage layer 14.

If the voltage applied to the gate electrode layer 18 becomes zero after electrons are stored in the charge storage layer 14, and the size of the first polarization domain 20a will be reduced, the electrons trapped in the first polarization domain 20a may be detrapped, and the density of the electrons stored in the charge storage layer 14 may decrease. If the density of the electrons stored in the charge storage layer 14 decreases, data in the memory cell 100 may be lost.

The charge storage layer 14 according to the first embodiment contains at least one second element selected from a group consisting of titanium (Ti), cerium (Ce), tantalum (Ta), tungsten (W), niobium (Nb), molybdenum (Mo), manganese (Mn), ruthenium (Ru), and tin (Sn). Since the charge storage layer 14 contains the second element, a decrease in the density of electrons stored in the charge storage layer 14 is suppressed even when the voltage applied to the gate electrode layer 18 becomes zero.

It is believed that, since the charge storage layer 14 contains the second element, a reduction in the size of the first polarization domain 20a is suppressed even when the voltage applied to the gate electrode layer 18 becomes zero. Specifically, for example, it is believed that the size of the first polarization domain 20a in the crystal grain 20 is fixed by pinning the movement of the domain wall by the second element contained in the crystal grain 20. That is, in a typical ferroelectric, the size of the polarization domain changes due to the external electric field as the reversal of the polarization domain propagates with the polarization domain wall as the front line. That is, the polarization domain facing the forward direction relative to the external electric field expands, while the polarization domain facing the reverse direction relative to the external electric field contracts. The expansion and contraction of the polarization domain occurs due to the movement of the polarization domain wall, but the second element has an effect of preventing the movement of the polarization domain wall.

Therefore, according to the memory cell 100 according to the first embodiment, a decrease in the density of the charges stored in the charge storage layer 14 is suppressed to improve the charge storage density of the charge storage layer 14.

In addition, since the charge storage layer 14 contains the second element, the number of first polarization domains 20a in the crystal grain 20 increases. This is believed to be because the second element contained in the crystal grain 20 promotes the formation of domain nuclei that grow into the first polarization domain 20a in the crystal grain 20 when a gate voltage is applied to the charge storage layer 14.

By increasing the number of first polarization domains 20a in the crystal grain 20, the amount of electrons that can be trapped in one crystal grain 20 increases, and accordingly, it is possible to further improve the charge storage density of the charge storage layer 14.

From the viewpoint of increasing the charge storage density of the charge storage layer 14, it is preferable that the charge storage layer 14 contains at least one third element selected from a group consisting of barium (Ba), strontium (Sr), and calcium (Ca). It is believed that when the crystal grain 20 contains the third element having an ionic radius larger than that of hafnium (Hf) or zirconium (Zr), the distortion of the crystal grain 20 increases and accordingly, the number of first polarization domains 20a in the crystal grain 20 or the complexity of the domain wall structure increases.

From the viewpoint of increasing the charge storage density of the charge storage layer 14, it is preferable that the charge storage layer 14 contains at least one fourth element selected from a group consisting of aluminum (Al) and silicon (Si). It is believed that when the crystal grain 20 contains the fourth element having an ionic radius smaller than that of hafnium (Hf) or zirconium (Zr), the distortion of the crystal grain 20 increases and accordingly, the number of first polarization domains 20a in the crystal grain 20 or the complexity of the domain wall structure increases.

From the viewpoint of increasing the charge storage density of the charge storage layer 14, it is preferable that the charge storage layer 14 contains both the third element and the fourth element. That is, atoms of the third element and atoms of the fourth element mainly substitute hafnium (Hf) atoms or zirconium (Zr) atoms, but the introduction of a third atom with an atomic radius significantly larger than that of the hafnium (Hf) atom or zirconium (Zr) atom or a fourth atom with an atomic radius significantly smaller than that of the hafnium (Hf) atom or zirconium (Zr) atom increases the distortion of the oxide crystal lattice containing hafnium (Hf) or zirconium (Zr). In particular, when the third atom and the fourth atom are not adjacent to each other or are not distant from each other but are present simultaneously with one to three hafnium (Hf) or zirconium (Zr) atoms separated, the distortion of the oxide lattice containing hafnium (Hf) or zirconium (Zr) further increases, resulting in a synergistic effect that increases the charge storage density of the charge storage layer 14.

It is preferable that the ratio of the atomic concentration of the second element to the atomic concentration of the first element in the crystal grain 20 is equal to or more than 1% and equal to or less than 9%. By setting the above ratio to be equal to or more than 1%, the charge storage density of the charge storage layer 14 increases. In addition, by setting the above ratio to be equal to or less than 9%, the crystal grains 20 in the charge storage layer 14 are stabilized. Therefore, the charge storage density is stabilized.

The median of the number of first polarization domains 20a included in each of the plurality of crystal grains 20 is preferably equal to or more than 3 and equal to or less than 100, and more preferably equal to or more than 5 and equal to or less than 20. By satisfying the above lower limit value, the charge storage density of the charge storage layer 14 increases. In addition, by satisfying the above upper limit value, the first polarization domain 20a can be easily formed. From the viewpoint of increasing the charge storage density, it is preferable that the domain wall 24 separating the domains from each other has a polygonal shape or a surface shape with many protrusions and recesses rather than a linear or planar shape.

As described above, according to the first embodiment, it is possible to realize a semiconductor memory device that enables an improvement in the charge storage density of the charge storage layer.

### Second Embodiment

A semiconductor memory device according to a second embodiment is different from the semiconductor memory device according to the first embodiment in that the first crystal does not include a second region, the first crystal has one space group selected from a group consisting of a space group Pca21 (space group number 29), a space group R3 (space group number 146), a space group R3m (space group number 160), and a space group Pmn21 (space group number 31), and a third region different from the first region is further included. Hereinafter, the description of a part of the content overlapping the first embodiment may be omitted.

The semiconductor memory device according to the second embodiment has a configuration similar to that of the memory cell 100 according to the first embodiment. A memory cell according to the second embodiment includes a charge storage layer 14x instead of the charge storage layer 14 of the memory cell 100 according to the first embodiment.

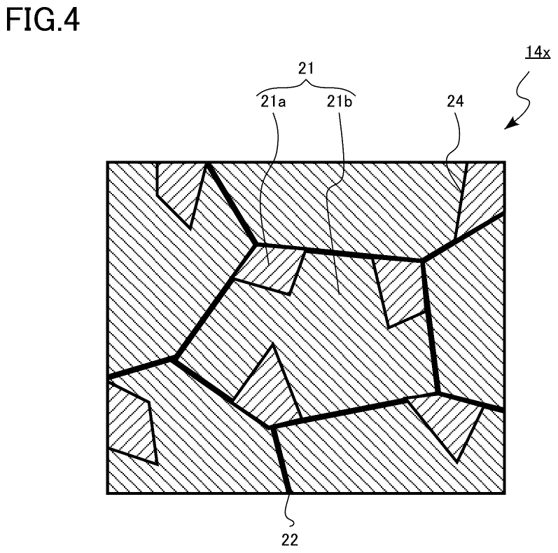

FIG. 4 is a schematic cross-sectional view of a part of a charge storage layer according to the second embodiment. FIG. 4 is a cross section parallel to a direction from the semiconductor layer 10 toward the gate electrode layer 18. In other words, FIG. 4 is a cross section perpendicular to the surface of the semiconductor layer 10.

The charge storage layer 14x according to the second embodiment is polycrystalline. The charge storage layer 14x contains a plurality of crystal grains 21. There is a grain boundary 22 between the crystal grains 21 adjacent to each other. Each of the plurality of crystal grains 21 is an example of the first crystal.

The crystal grain 21 contains: at least one first element selected from a group consisting of hafnium (Hf) and zirconium (Zr); at least one second element selected from a group consisting of titanium (Ti), cerium (Ce), tantalum (Ta), tungsten (W), niobium (Nb), molybdenum (Mo), manganese (Mn), ruthenium (Ru), and tin (Sn); and oxygen (O).

The crystal grain 21 is, for example, a hafnium oxide or a zirconium oxide. The charge storage layer 14x is, for example, a hafnium oxide containing zirconium (Zr). In addition, the charge storage layer 14x is, for example, a zirconium oxide containing hafnium (Hf).

The crystal grain 21 contains, for example, hafnium oxide or zirconium oxide as a main component.

The crystal grain 21 contains, for example, hafnium oxide as a main component. Among the elements contained in the crystal grains 21, the atomic ratio of hafnium (Hf) and oxygen (O) is, for example, equal to or more than 90%.

Among the elements contained in the crystal grains 21, the atomic ratio of hafnium (Hf), zirconium (Zr), and oxygen (O) is, for example, equal to or more than 90%.

The crystal grain 21 contains, for example, zirconium oxide as a main component. Among the elements contained in the crystal grains 21, the atomic ratio of zirconium (Zr) and oxygen (O) is, for example, equal to or more than 90%. Among the elements contained in the crystal grains 21, the atomic ratio of zirconium (Zr), hafnium (Hf), and oxygen (O) is, for example, equal to or more than 90%.

The crystal grain 21 contains at least one second element selected from a group consisting of titanium (Ti), cerium (Ce), tantalum (Ta), tungsten (W), niobium (Nb), molybdenum (Mo), manganese (Mn), ruthenium (Ru), and tin (Sn). The ratio of the atomic concentration of the second element to the atomic concentration of the first element in the crystal grain 21 is, for example, equal to or more than 1% and equal to or less than 9%.

The crystal grain 21 contains, for example, at least one third element selected from a group consisting of barium (Ba), strontium (Sr), and calcium (Ca). The crystal grain 21 contains, for example, at least one fourth element selected from a group consisting of aluminum (Al) and silicon (Si). The charge storage layer 14x contains, for example, the third element and the fourth element.

The median of the long diameters of the crystal grains 21 is, for example, equal to or more than 1 nm and equal to or less than 5 nm. The median of the long diameters of the crystal grains 21 is, for example, equal to or more than one-twentieth and equal to or less than one-half the thickness of the charge storage layer 14x in a direction from the semiconductor layer 10 toward the gate electrode layer 18.

The crystal grain 21 includes a first polarization domain 21a and a second polarization domain 21b. The crystal grain 21 includes, for example, a plurality of first polarization domains 21a and a plurality of second polarization domains 21b. There is a domain wall 24 between a plurality of first polarization domains 21a and second polarization domains 21b adjacent to each other.

The first polarization domain 21a is an example of the first region. The second polarization domain 21b is an example of the third region. The first polarization domain 21a and the second polarization domain 21b are examples of a polarization domain.

The median of the number of first polarization domains 21a included in each of the plurality of crystal grains 21 is equal to or more than 3 and equal to or less than 100.

The first polarization domain 21a has one space group selected from a group consisting of the space group Pca21 (space group number 29), the space group R3 (space group number 146), the space group R3m (space group number 160), and the space group Pmn21 (space group number 31). A hafnium oxide or a zirconium oxide having the space group Pca21 (space group number 29), the space group R3 (space group number 146), the space group R3m (space group number 160), or the space group Pmn21 (space group number 31) is a ferroelectric. The first polarization domain 21a has ferroelectric properties.

The second polarization domain 21b has one space group selected from a group consisting of a space group Pca21 (space group number 29), a space group R3 (space group number 146), a space group R3m (space group number 160), and a space group Pmn21 (space group number 31). A hafnium oxide or a zirconium oxide having the space group Pca21 (space group number 29), the space group R3 (space group number 146), the space group R3m (space group number 160), or the space group Pmn21 (space group number 31) is a ferroelectric. The second polarization domain 21b has ferroelectric properties.

The space group of the second polarization domain 21b and the space group of the first polarization domain 21a are, for example, the same. The second polarization domain 21b and the first polarization domain 21a have different polarization directions.

The semiconductor memory device according to the second embodiment can be manufactured, for example, by adjusting the type and content ratio of each element, the conditions of formation of the hafnium oxide film, or the conditions of crystallization annealing in the method for manufacturing the semiconductor memory device according to the first embodiment. Annealing in other manufacturing procedures may serve as the crystallization annealing.

Next, the function and effect of the semiconductor memory device according to the second embodiment will be described.

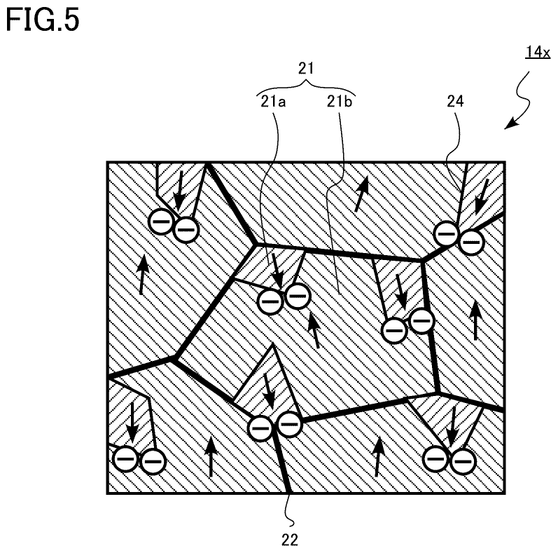

FIG. 5 is an explanatory diagram of the function and effect of the semiconductor memory device according to the second embodiment. FIG. 5 is a schematic cross-sectional view of a part of the charge storage layer according to the second embodiment. FIG. 5 is a diagram corresponding to FIG. 4. In addition, the arrows in FIG. 5 indicate the polarization direction of each polarization domain.

FIG. 5 is a diagram showing a state in which a write voltage is applied between the semiconductor layer 10 and the gate electrode layer 18 to store electrons in the charge storage layer 14x. When electrons are stored in the charge storage layer 14x, for example, a gate voltage that is positive with respect to the semiconductor layer 10 is applied to the gate electrode layer 18, thereby injecting electrons from the semiconductor layer 10 into the charge storage layer 14x.

Due to the gate voltage applied to the gate electrode layer 18, a plurality of first polarization domains 21a are formed in the crystal grain 21. The first polarization domain 20a has ferroelectric properties, and is polarized by the application of the gate voltage so that the semiconductor layer 10 side is positive and the gate electrode layer 18 side is negative.

As shown in FIG. 5, the electrons injected into the charge storage layer 14x are trapped by the domain wall 24 on the semiconductor layer 10 side of the first polarization domain 21a, and the electrons are stored in the charge storage layer 14x.

If the voltage applied to the gate electrode layer 18 becomes zero after electrons are stored in the charge storage layer 14x, and the size of the first polarization domain 21a will be reduced, the electrons trapped in the first polarization domain 21a may be detrapped, and the density of the electrons stored in the charge storage layer 14x may decrease. If the density of the electrons stored in the charge storage layer 14x decreases, data in the memory cell may be lost.

The charge storage layer 14x according to the second embodiment contains at least one second element selected from a group consisting of titanium (Ti), cerium (Ce), tantalum (Ta), tungsten (W), niobium (Nb), molybdenum (Mo), manganese (Mn), ruthenium (Ru), and tin (Sn), similarly to the charge storage layer 14 according to the first embodiment.

Therefore, according to the memory cell according to the second embodiment, due to the same function as the charge storage layer 14 according to the first embodiment, a decrease in the density of the charges stored in the charge storage layer 14x is suppressed to improve the charge storage density of the charge storage layer 14x.

From the viewpoint of increasing the charge storage density of the charge storage layer 14x, it is preferable that the charge storage layer 14x contains at least one third element selected from a group consisting of barium (Ba), strontium (Sr), and calcium (Ca).

From the viewpoint of increasing the charge storage density of the charge storage layer 14x, it is preferable that the charge storage layer 14x contains at least one fourth element selected from a group consisting of aluminum (Al) and silicon (Si).

From the viewpoint of increasing the charge storage density of the charge storage layer 14x, it is preferable that the charge storage layer 14x contains both the third element and the fourth element.

It is preferable that the ratio of the atomic concentration of the second element to the atomic concentration of the first element in the crystal grain 21 is equal to or more than 1% and equal to or less than 9%.

The median of the number of first polarization domains 21a included in each of the plurality of crystal grains 21 is preferably equal to or more than 3 and equal to or less than 100, and more preferably equal to or more than 5 and equal to or less than 20. From the viewpoint of increasing the charge storage density, it is preferable that the domain wall 24 separating the domains from each other has a polygonal shape or a surface shape with many protrusions and recesses rather than a linear or planar shape.

As described above, according to the second embodiment, it is possible to realize a semiconductor memory device that enables an improvement in the charge storage density of the charge storage layer.

### Third Embodiment

A semiconductor memory device according to a third embodiment is different from the semiconductor memory device according to the first embodiment in that the charge storage layer includes a matrix region surrounding at least one first crystal. Hereinafter, the description of a part of the content overlapping the first embodiment may be omitted.

The semiconductor memory device according to the third embodiment has a configuration similar to that of the memory cell 100 according to the first embodiment. The memory cell according to the third embodiment includes a charge storage layer 14y instead of the charge storage layer 14 of the memory cell 100 according to the first embodiment.

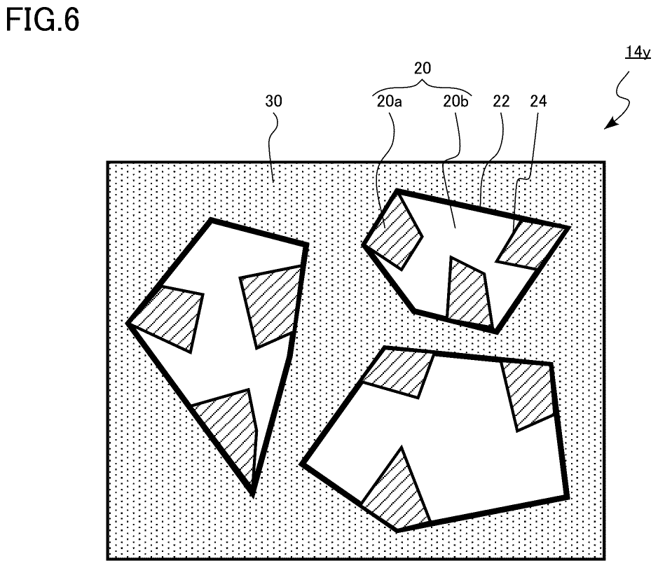

FIG. 6 is a schematic cross-sectional view of a part of the charge storage layer according to the third embodiment. FIG. 6 is a cross section parallel to a direction from the semiconductor layer 10 toward the gate electrode layer 18. In other words, FIG. 6 is a cross section perpendicular to the surface of the semiconductor layer 10.

The charge storage layer 14y according to the third embodiment includes a plurality of crystal grains 20 and a matrix region 30. The plurality of crystal grains 20 are dispersed in the matrix region 30. The matrix region 30 surrounds the plurality of crystal grains 20.

The crystal grain 20 in the third embodiment has a configuration similar to that of the crystal grain 20 in the first embodiment.

The matrix region 30 is amorphous or polycrystalline. When the matrix region 30 is polycrystalline, the median of the long diameters of crystals contained in the matrix region 30 is smaller than the median of the long diameters of the crystal grains 20, for example.

The matrix region 30 contains: at least one first element selected from a group consisting of hafnium (Hf) and zirconium (Zr); at least one second element selected from a group consisting of titanium (Ti), cerium (Ce), tantalum (Ta), tungsten (W), niobium (Nb), molybdenum (Mo), manganese (Mn), ruthenium (Ru), and tin (Sn); and oxygen (O).

The matrix region 30 is, for example, a hafnium oxide or a zirconium oxide. The matrix region 30 is, for example, a hafnium oxide containing zirconium (Zr). In addition, the matrix region 30 is, for example, a zirconium oxide containing hafnium (Hf).

The matrix region 30 contains, for example, hafnium oxide or zirconium oxide as a main component.

The matrix region 30 contains, for example, hafnium oxide as a main component. Among the elements contained in the matrix region 30, the atomic ratio of hafnium (Hf) and oxygen (O) is, for example, equal to or more than 60%. Among the elements contained in the matrix region 30, the atomic ratio of hafnium (Hf), zirconium (Zr), and oxygen (O) is, for example, equal to or more than 60%.

The matrix region 30 contains, for example, zirconium oxide as a main component. Among the elements contained in the matrix region 30, the atomic ratio of zirconium (Zr) and oxygen (O) is, for example, equal to or more than 60%. Among the elements contained in the matrix region 30, the atomic ratio of zirconium (Zr), hafnium (Hf), and oxygen (O) is, for example, equal to or more than 60%.

The matrix region 30 contains at least one second element selected from a group consisting of titanium (Ti), cerium (Ce), tantalum (Ta), tungsten (W), niobium (Nb), molybdenum (Mo), manganese (Mn), ruthenium (Ru), and tin (Sn). The ratio of the atomic concentration of the second element to the atomic concentration of the first element in the crystal grain 20 is, for example, equal to or more than 1% and equal to or less than 40%.

The matrix region 30 contains, for example, at least one third element selected from a group consisting of barium (Ba), strontium (Sr), and calcium (Ca). The matrix region 30 contains, for example, at least one fourth element selected from a group consisting of aluminum (Al) and silicon (Si). The matrix region 30 contains, for example, the third element and the fourth element.

The chemical composition of the matrix region 30 is different from, for example, the chemical composition of the crystal grains 20. For example, the atomic concentration of the second element contained in the crystal grain 20 is lower than the atomic concentration of the second element contained in the matrix region 30. In addition, for example, the atomic concentration of the third element contained in the crystal grain 20 is lower than the atomic concentration of the third element contained in the matrix region 30. In addition, for example, the atomic concentration of the fourth element contained in the crystal grain 20 is lower than the atomic concentration of the fourth element contained in the matrix region 30.

The semiconductor memory device according to the third embodiment can be manufactured, for example, by adjusting the type and content ratio of each element, the conditions of formation of the hafnium oxide film, or the conditions of crystallization annealing in the method for manufacturing the semiconductor memory device according to the first embodiment.

Next, the function and effect of the semiconductor memory device according to the third embodiment will be described.

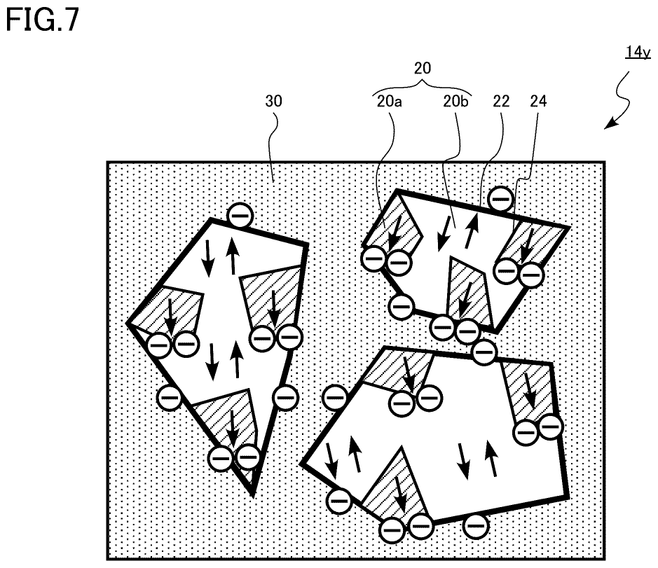

FIG. 7 is an explanatory diagram of the function and effect of the semiconductor memory device according to the third embodiment. FIG. 7 is a schematic cross-sectional view of a part of the charge storage layer according to the third embodiment. FIG. 7 is a diagram corresponding to FIG. 6. In addition, the arrows in FIG. 7 indicate the polarization direction of each polarization domain.

FIG. 7 is a diagram showing a state in which a write voltage is applied between the semiconductor layer 10 and the gate electrode layer 18 to store electrons in the charge storage layer 14y. When electrons are stored in the charge storage layer 14y, for example, a gate voltage that is positive with respect to the semiconductor layer 10 is applied to the gate electrode layer 18, thereby injecting electrons from the semiconductor layer 10 into the charge storage layer 14y.

Due to the gate voltage applied to the gate electrode layer 18, a plurality of first polarization domains 20a are formed in the crystal grain 20. The first polarization domain 20a has one space group selected from a group consisting of a space group Pca21 (space group number 29), a space group R3 (space group number 146), a space group R3m (space group number 160), and a space group Pmn21 (space group number 31). The space groups are space groups of crystal structure which exhibit ferroelectric properties.

As shown in FIG. 7, the electrons injected into the charge storage layer 14y are trapped by the domain wall 24 on the semiconductor layer 10 side of the first polarization domain 20a, and the electrons are stored in the charge storage layer 14y.

According to the memory cell according to the third embodiment, due to the same function as the memory cell 100 according to the first embodiment, a decrease in the density of the charges stored in the charge storage layer 14y is suppressed to improve the charge storage density of the charge storage layer 14y.

In addition, in the charge storage layer 14y according to the third embodiment, as shown in FIG. 7, electrons are also trapped in the grain boundary 22 between the crystal grain 20 and the matrix region 30. Therefore, the charge storage density of the charge storage layer 14y is further improved.

In addition, since the charge storage layer 14y contains the second element, the grain size of the crystal grain 20 can be reduced. As the grain size of the crystal grain 20 becomes smaller, the first polarization domain 20a becomes more easily fixed in the crystal grain 20. Therefore, the charge storage density of the charge storage layer 14y is further improved. In addition, as the grain size of the crystal grain 20 becomes smaller, the area of the grain boundary 22 between the crystal grain 20 and the matrix region 30 also becomes larger. Therefore, the charge storage density of the charge storage layer 14y is further improved.

From the viewpoint of increasing the charge storage density of the charge storage layer 14y, it is preferable that the charge storage layer 14y contains at least one third element selected from a group consisting of barium (Ba), strontium (Sr), and calcium (Ca). From the viewpoint of increasing the charge storage density of the charge storage layer 14y, it is preferable that the charge storage layer 14y contains at least one fourth element selected from a group consisting of aluminum (Al) and silicon (Si). From the viewpoint of increasing the charge storage density of the charge storage layer 14y, it is preferable that the charge storage layer 14y contains both the third element and the fourth element.

It is preferable that the ratio of the atomic concentration of the second element to the atomic concentration of the first element in the crystal grain 20 is equal to or more than 1% and equal to or less than 9%.

The median of the number of first polarization domains 20a included in each of the plurality of crystal grains 20 is preferably equal to or more than 3 and equal to or less than 100, and more preferably equal to or more than 5 and equal to or less than 20. From the viewpoint of increasing the charge storage density, it is preferable that the domain wall 24 separating the domains from each other has a polygonal shape or a surface shape with many protrusions and recesses rather than a linear or planar shape.

The crystal contained in the matrix region 30 is, for example, a paraelectric. The crystal contained in the matrix region 30 is, for example, a hafnium oxide or a zirconium oxide of a space group P21/c (space group number 14).

The crystal contained in the matrix region 30 may be, for example, a ferroelectric. When the crystal contained in the matrix region 30 is a ferroelectric, it is preferable that the polarization direction in the crystal is a direction along the surface of the semiconductor layer 10. Since the polarization direction in the crystal is a direction along the surface of the semiconductor layer 10, the effect of the ferroelectric properties of the matrix region 30 on the charge storage density of the charge storage layer 14y is reduced apparently.

As described above, according to the third embodiment, it is possible to realize a semiconductor memory device that enables an improvement in the charge storage density of the charge storage layer.

### Fourth Embodiment

A semiconductor memory device according to a fourth embodiment is different from the semiconductor memory device according to the second embodiment in that the charge storage layer includes a matrix region surrounding at least one first crystal. In addition, the semiconductor memory device according to the fourth embodiment is different from the semiconductor memory device according to the third embodiment in that the configuration of the first crystal is different. Hereinafter, the description of a part of the content overlapping the second or third embodiment may be omitted.

The semiconductor memory device according to the fourth embodiment has a configuration similar to that of the memory cell 100 according to the first embodiment. A memory cell according to the fourth embodiment includes a charge storage layer 14z instead of the charge storage layer 14 of the memory cell 100 according to the first embodiment.

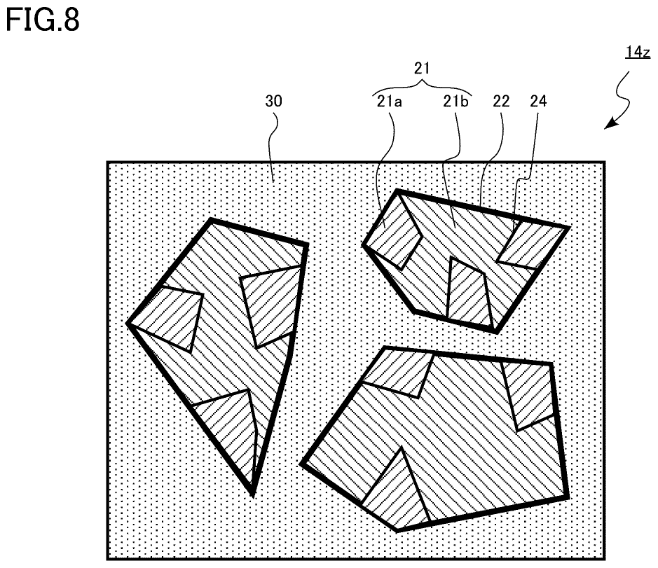

FIG. 8 is a schematic cross-sectional view of a part of the charge storage layer according to the fourth embodiment. FIG. 8 is a cross section parallel to a direction from the semiconductor layer 10 toward the gate electrode layer 18. In other words, FIG. 8 is a cross section perpendicular to the surface of the semiconductor layer 10.

The charge storage layer 14z in the fourth embodiment includes a plurality of crystal grains 21 and a matrix region 30. The plurality of crystal grains 21 are dispersed in the matrix region 30. The matrix region 30 surrounds the plurality of crystal grains 21.

The crystal grain 21 in the fourth embodiment has a configuration similar to that of the crystal grain 21 in the second embodiment. The matrix region 30 in the fourth embodiment has a configuration similar to that of the matrix region 30 in the third embodiment.

The semiconductor memory device according to the fourth embodiment can be manufactured, for example, by adjusting the type and content ratio of each element, the conditions of formation of the hafnium oxide film, or the conditions of crystallization annealing in the method for manufacturing the semiconductor memory device according to the first embodiment.

Next, the function and effect of the semiconductor memory device according to the fourth embodiment will be described.

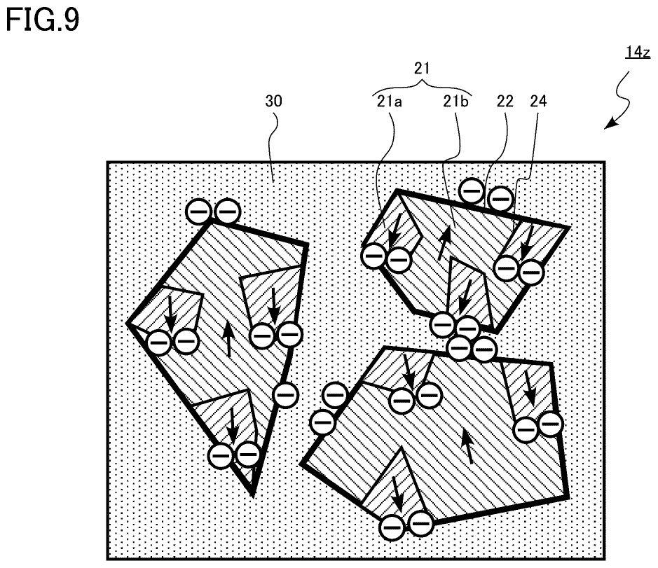

FIG. 9 is an explanatory diagram of the function and effect of the semiconductor memory device according to the fourth embodiment. FIG. 9 is a schematic cross-sectional view of a part of the charge storage layer according to the fourth embodiment. FIG. 9 is a diagram corresponding to FIG. 8. In addition, the arrows in FIG. 9 indicate the polarization direction of each polarization domain.

FIG. 9 is a diagram showing a state in which a write voltage is applied between the semiconductor layer 10 and the gate electrode layer 18 to store electrons in the charge storage layer 14z. When electrons are stored in the charge storage layer 14z, for example, a gate voltage that is positive with respect to the semiconductor layer 10 is applied to the gate electrode layer 18, thereby injecting electrons from the semiconductor layer 10 into the charge storage layer 14z.

Due to the gate voltage applied to the gate electrode layer 18, a plurality of first polarization domains 21a are formed in the crystal grain 21. The first polarization domain 21a has ferroelectric properties, and is polarized by the application of the gate voltage so that the semiconductor layer 10 side is positive and the gate electrode layer 18 side is negative.

As shown in FIG. 9, the electrons injected into the charge storage layer 14z are trapped by the domain wall 24 on the semiconductor layer 10 side of the first polarization domain 21a, and the electrons are stored in the charge storage layer 14z.

According to the memory cell according to the fourth embodiment, similarly to the memory cell according to the second embodiment, a decrease in the density of the charges stored in the charge storage layer 14z is suppressed to improve the charge storage density of the charge storage layer 14z.

In addition, in the charge storage layer 14z according to the fourth embodiment, as shown in FIG. 9, electrons are also trapped in the grain boundary 22 between the crystal grains 21 and the matrix region 30. Therefore, the charge storage density of the charge storage layer 14z is further improved.

In addition, since the charge storage layer 14z contains the second element, the grain size of the crystal grain 21 can be reduced. As the grain size of the crystal grain 21 becomes smaller, the first polarization domain 21a becomes more easily fixed in the crystal grain 21. Therefore, the charge storage density of the charge storage layer 14z is further improved. In addition, as the grain size of the crystal grains 21 becomes smaller, the area of the grain boundary 22 between the crystal grains 21 and the matrix region 30 also becomes larger. Therefore, the charge storage density of the charge storage layer 14z is further improved.

From the viewpoint of increasing the charge storage density of the charge storage layer 14z, it is preferable that the charge storage layer 14z contains at least one third element selected from a group consisting of barium (Ba), strontium (Sr), and calcium (Ca). From the viewpoint of increasing the charge storage density of the charge storage layer 14z, it is preferable that the charge storage layer 14z contains at least one fourth element selected from a group consisting of aluminum (Al) and silicon (Si). From the viewpoint of increasing the charge storage density of the charge storage layer 14z, it is preferable that the charge storage layer 14z contains both the third element and the fourth element.

It is preferable that the ratio of the atomic concentration of the second element to the atomic concentration of the first element in the crystal grain 21 is equal to or more than 1% and equal to or less than 9%.

The median of the number of first polarization domains 21a included in each of the plurality of crystal grains 21 is preferably equal to or more than 3 and equal to or less than 100, and more preferably equal to or more than 5 and equal to or less than 20. From the viewpoint of increasing the charge storage density, it is preferable that the domain wall 24 separating the domains from each other has a polygonal shape or a surface shape with many protrusions and recesses rather than a linear or planar shape.

The crystal contained in the matrix region 30 is, for example, a paraelectric. The crystal contained in the matrix region 30 is, for example, a hafnium oxide or a zirconium oxide of a space group P21/c (space group number 14).

The crystal contained in the matrix region 30 may be, for example, a ferroelectric. When the crystal contained in the matrix region 30 is a ferroelectric, it is preferable that the polarization direction in the crystal is a direction along the surface of the semiconductor layer 10.

As described above, according to the fourth embodiment, it is possible to realize a semiconductor memory device that enables an improvement in the charge storage density of the charge storage layer.

### Fifth Embodiment

A semiconductor memory device according to a fifth embodiment includes: a plurality of gate electrode layers arranged in a first direction so as to be spaced from each other; a semiconductor layer extending in the first direction; a first insulating layer provided between the semiconductor layer and at least one of the plurality of gate electrode layers; a second insulating layer provided between the first insulating layer and the at least one gate electrode layer; and a charge storage layer provided between the first insulating layer and the second insulating layer, containing at least one first crystal including a first region having one space group selected from a group consisting of a space group Pca21 (space group number 29), a space group R3 (space group number 146), a space group R3m (space group number 160), and a space group Pmn21 (space group number 31), and containing at least one first element selected from a group consisting of hafnium (Hf) and zirconium (Zr), at least one second element selected from a group consisting of titanium (Ti), cerium (Ce), tantalum (Ta), tungsten (W), niobium (Nb), molybdenum (Mo), manganese (Mn), ruthenium (Ru), and tin (Sn), and oxygen (O). The semiconductor memory device according to the fifth embodiment is different from the semiconductor memory devices according to the first to fourth embodiments in that a structure similar to those of the memory cells according to the first to fourth embodiments is applied to a three-dimensional NAND flash memory. Hereinafter, the description of a part of the content overlapping the first to fourth embodiments will be omitted.

The semiconductor memory device according to the fifth embodiment is a three-dimensional NAND flash memory. A memory cell of the semiconductor memory device according to the fifth embodiment is a so-called charge trap type memory cell.

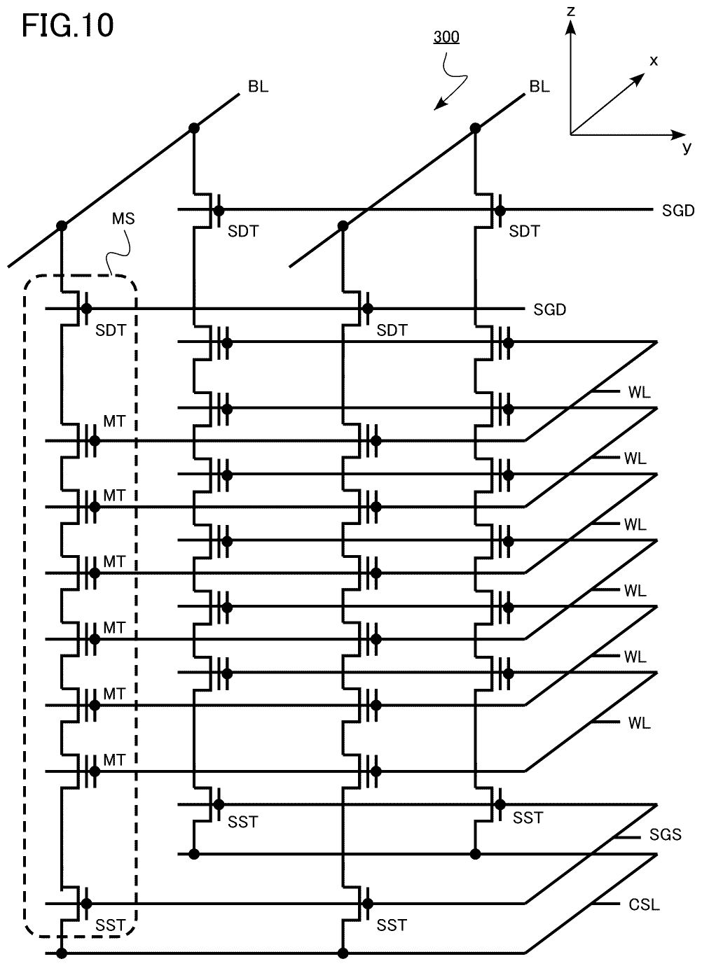

FIG. 10 is an equivalent circuit diagram of a memory cell array of the semiconductor memory device according to the fifth embodiment.

As shown in FIG. 10, a memory cell array 300 of the three-dimensional NAND flash memory according to the fifth embodiment includes a plurality of word lines WL, a common source line CSL, a source selection gate line SGS, a plurality of drain selection gate lines SGD, a plurality of bit lines BL, and a plurality of memory strings MS. The word line WL is an example of a gate electrode layer.

The plurality of word lines WL are arranged in the z direction so as to be spaced from each other. The plurality of word lines WL are arranged so as to be stacked in the z direction. The plurality of memory strings MS extend in the z direction. The plurality of bit lines BL extend in the x direction, for example.

Hereinafter, the x direction is defined as a second direction, the y direction is defined as a third direction, and the z direction is defined as a first direction. The x direction, the y direction, and the z direction are, for example, perpendicular to each other.

As shown in FIG. 10, each memory string MS includes a source selection transistor SST, a plurality of memory cells, and a drain selection transistor SDT connected in series to each other between the common source line CSL and the bit line BL. One memory string MS can be selected by selecting one bit line BL and one drain selection gate line SGD, and one memory cell can be selected by selecting one word line WL. The word line WL is a gate electrode of a memory cell transistor MT forming the memory cell.

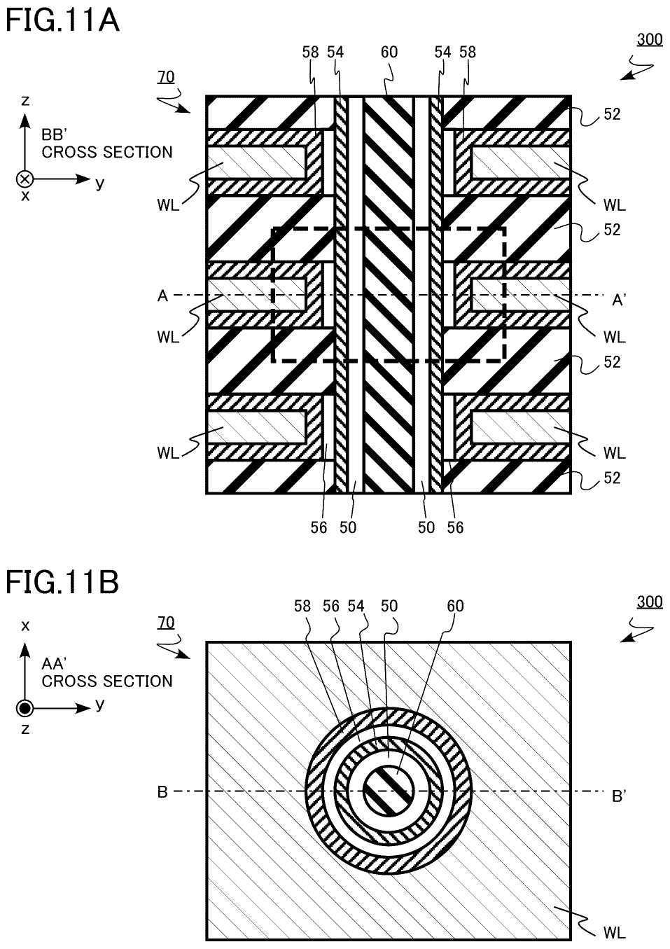

FIGS. 11A and 11B are schematic cross-sectional views of a memory cell array of the semiconductor memory device according to the fifth embodiment. FIGS. 11A and 11B show cross sections of a plurality of memory cells, for example, in one memory string MS surrounded by the dotted line in the memory cell array 300 in FIG. 10.

FIG. 11A is a yz cross-sectional view of the memory cell array 300. FIG. 11A is a cross section taken along the line BB′ of FIG. 11B. FIG. 11B is an xy cross-sectional view of the memory cell array 300. FIG. 11B is a cross section taken along the line AA′ of FIG. 11A. In FIG. 11A, a region surrounded by the dashed line is one memory cell.

As shown in FIGS. 11A and 11B, the memory cell array 300 includes a plurality of word lines WL, a semiconductor layer 50, a plurality of interlayer insulating layers 52, a tunnel insulating layer 54, a charge storage layer 56, a block insulating layer 58, and a core insulating region 60. The structure shown in FIGS. 11A and 11B does not necessarily have to be adopted, but it is preferable to have a structure in which the charge storage layer 56 of one memory cell surrounded by the dashed line in FIG. 11A is a region separated from the charge storage layer 56 of a memory cell adjacent in the z direction rather than a region continuous with the charge storage layer 56 of the memory cell adjacent in the z direction.

The plurality of word lines WL and the plurality of interlayer insulating layers 52 form a stacked body 70.

The word line WL is an example of a gate electrode layer. The tunnel insulating layer 54 is an example of the first insulating layer. The block insulating layer 58 is an example of the second insulating layer.

The memory cell array 300 is provided, for example, on a semiconductor substrate (not shown). The semiconductor substrate has a surface parallel to the x and y directions.

The word line WL and the interlayer insulating layer 52 are alternately stacked in the z direction on the semiconductor substrate. The word lines WL are arranged so as to be spaced from each other in the z direction. The word lines WL are repeatedly arranged in the z direction so as to be spaced from each other. A plurality of word lines WL and a plurality of interlayer insulating layers 52 form the stacked body 70. The word line WL functions as a control electrode of the memory cell transistor MT.

The word line WL is a plate-shaped conductor. The word line WL is, for example, a metal, a metal nitride, a metal carbide, or a semiconductor. The word line WL is, for example, tungsten (W). The thickness of the word line WL in the z direction is, for example, equal to or more than 5 nm and equal to or less than 20 nm.

The interlayer insulating layer 52 separates the word line WL and the word line WL from each other. The interlayer insulating layer 52 electrically separates the word line WL and the word line WL from each other.

The interlayer insulating layer 52 is, for example, an oxide, an oxynitride, or a nitride. The interlayer insulating layer 52 is, for example, a silicon oxide. The thickness of the interlayer insulating layer 52 in the z direction is, for example, equal to or more than 5 nm and equal to or less than 20 nm.

The semiconductor layer 50 is provided in the stacked body 70. The semiconductor layer 50 extends in the z-direction. The semiconductor layer 50 extends in a direction perpendicular to the surface of the semiconductor substrate.

The semiconductor layer 50 is provided so as to penetrate the stacked body 70. The semiconductor layer 50 is surrounded by a plurality of word lines WL. The semiconductor layer 50 has, for example, a cylindrical shape. The semiconductor layer 50 functions as a channel of the memory cell transistor MT.

The semiconductor layer 50 is, for example, a polycrystalline semiconductor. The semiconductor layer 50 is, for example, a polycrystalline silicon.

The tunnel insulating layer 54 is provided between the semiconductor layer 50 and the word line WL. The tunnel insulating layer 54 is provided between the semiconductor layer 50 and at least one of the plurality of word lines WL. The tunnel insulating layer 54 is provided between the semiconductor layer 50 and the charge storage layer 56.

The tunnel insulating layer 54 has a function of allowing charges to pass therethrough according to the voltage applied between the word line WL and the semiconductor layer 10.

The tunnel insulating layer 54 is, for example, an oxide, an oxynitride, or a nitride. The tunnel insulating layer 12 contains, for example, silicon oxide, silicon oxynitride, or silicon nitride. The thickness of the tunnel insulating layer 12 is, for example, equal to or more than 3 nm and equal to or less than 8 nm.

The charge storage layer 56 is provided between the tunnel insulating layer 54 and the block insulating layer 58. The charge storage layers 56 adjacent to each other in the z direction are, for example, spaced from each other. The charge storage layers 56 adjacent to each other in the z direction are, for example, physically separated from each other. In addition, the charge storage layers 56 adjacent to each other in the z direction may be continuous, for example.

The charge storage layer 56 has a function of trapping and storing charges. The charge is, for example, an electron. The threshold voltage of the memory cell transistor MT changes according to the amount of charge stored in the charge storage layer 56. By using the threshold voltage change, one memory cell can store data.

For example, when the threshold voltage of the memory cell transistor MT changes, the voltage at which the memory cell transistor MT is turned on changes. For example, if a state in which the threshold voltage is high is defined as data “0” and a state in which the threshold voltage is low is defined as data “1”, the memory cell can store 1-bit data of “0” and “1”.

The charge storage layer 56 has a configuration similar to that of the charge storage layer 14 according to the first embodiment, the charge storage layer 14x according to the second embodiment, the charge storage layer 14y according to the third embodiment, or the charge storage layer 14z according to the fourth embodiment.

The thickness of the charge storage layer 56 in a direction from the semiconductor layer 50 toward the word line WL is, for example, equal to or more than 2 nm and equal to or less than 10 nm.

The block insulating layer 58 is provided between the tunnel insulating layer 54 and the word line WL. The block insulating layer 58 is provided between the charge storage layer 56 and the word line WL. The block insulating layer 58 has a function of blocking the current flowing between the charge storage layer 56 and the word line WL.

The block insulating layer 58 is, for example, an oxide, an oxynitride, or a nitride. The block insulating layer 58 contains, for example, silicon oxide or aluminum oxide.

The core insulating region 60 is provided in the stacked body 70. The core insulating region 60 extends in the z direction. The core insulating region 60 is provided so as to penetrate the stacked body 70. The core insulating region 60 is surrounded by the semiconductor layer 50. The core insulating region 60 is surrounded by a plurality of word lines WL. The core insulating region 60 has a columnar shape. The core insulating region 60 has, for example, a cylindrical shape.

The core insulating region 60 is, for example, an oxide, an oxynitride, or a nitride. The core insulating region 60 is, for example, a silicon oxide.

The charge storage layer 56 of the three-dimensional NAND flash memory according to the fifth embodiment has a large charge storage density. Therefore, since the charge storage layer 56 can be made thinner, it is possible to reduce the diameter of the memory hole. As a result, it is possible to scale down the memory cell and accordingly, further increase the memory capacity.

As described above, according to the fifth embodiment, it is possible to realize a semiconductor memory device that enables an improvement in the charge storage density of the charge storage layer as in the first to fourth embodiments. In addition, since it is possible to scale down the memory cell, it is possible to further increase the memory capacity.

In the first to fifth embodiments, the case where the charges stored in the charge storage layer are electrons has been described as an example. However, the charges stored in the charge storage layer may be holes.

In the fifth embodiment, the case where the word line WL is a plate-shaped conductor has been described as an example. However, the shape of the word line WL is not necessarily limited to the plate shape. For example, the word line may be in the form of a stripe extending in the y direction.

In the fifth embodiment, the case where the semiconductor layer 50 has a cylindrical shape has been described as an example. However, the semiconductor layer 50 is not necessarily limited to having a cylindrical shape. The semiconductor layer 50 may have, for example, columnar shape or a rectangular prism shape.

In addition, in the fifth embodiment, the configuration in which the semiconductor layer 50 extends in a direction perpendicular to the surface of the semiconductor substrate has been described as an example. However, the semiconductor layer 50 may extend in a direction parallel to the surface of the semiconductor substrate, for example.

While certain embodiments have been described, these embodiments have been presented by way of example only, and are not intended to limit the scope of the inventions. Indeed, the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a semiconductor layer;
a gate electrode layer;
a first insulating layer provided between the semiconductor layer and the gate electrode layer;
a second insulating layer provided between the first insulating layer and the gate electrode layer; and
a charge storage layer provided between the first insulating layer and the second insulating layer, the charge storage layer including at least one first crystal including a first region having one space group selected from a group consisting of a space group Pca21 (space group number 29), a space group R3 (space group number 146), a space group R3m (space group number 160), and a space group Pmn21 (space group number 31), and the charge storage layer containing oxygen (O), at least one first element selected from a group consisting of hafnium (Hf) and zirconium (Zr), and at least one second element selected from a group consisting of titanium (Ti), cerium (Ce), tantalum (Ta), tungsten (W), niobium (Nb), molybdenum (Mo), manganese (Mn), ruthenium (Ru), and tin (Sn).

2. The semiconductor memory device according to claim 1,
wherein the at least one first crystal further includes a second region having one space group selected from a group consisting of a space group P42/nmc (space group number 137), a space group Pbca (space group number 61), and a space group Pbcm (space group number 57).

3. The semiconductor memory device according to claim 1,
wherein the at least one first crystal further includes a third region different from the first region and having one space group selected from a group consisting of a space group Pca21 (space group number 29), a space group R3 (space group number 146), a space group R3m (space group number 160), and a space group Pmn21 (space group number 31).

4. The semiconductor memory device according to claim 1,
wherein the charge storage layer further contains at least one third element selected from a group consisting of barium (Ba), strontium (Sr), and calcium (Ca).

5. The semiconductor memory device according to claim 1,
wherein the charge storage layer further contains at least one fourth element selected from a group consisting of aluminum (Al) and silicon (Si).

6. The semiconductor memory device according to claim 1,
wherein a median of a long diameter of the at least one first crystal is equal to or more than 1 nm and equal to or less than 5 nm.

7. The semiconductor memory device according to claim 1,
wherein a median of a long diameter of the at least one first crystal is equal to or less than half a thickness of the charge storage layer.

8. The semiconductor memory device according to claim 1,
wherein the charge storage layer includes a matrix region surrounding the at least one first crystal.

9. The semiconductor memory device according to claim 8,
wherein the matrix region is amorphous.

10. The semiconductor memory device according to claim 8,
wherein the matrix region contains the second element, and an atomic concentration of the second element in the first crystal is lower than an atomic concentration of the second element in the matrix region.

11. The semiconductor memory device according to claim 1,
wherein each of the at least one first crystal includes a plurality of polarization domains, and a median of the number of the plurality of polarization domains included in each of the at least one first crystal is equal to or more than 3 and equal to or less than 100.

12. A semiconductor memory device, comprising:
a plurality of gate electrode layers arranged in a first direction so as to be spaced from each other;
a semiconductor layer extending in the first direction;
a first insulating layer provided between the semiconductor layer and at least one of the plurality of gate electrode layers;
a second insulating layer provided between the first insulating layer and the at least one of the plurality of gate electrode layers; and
a charge storage layer provided between the first insulating layer and the second insulating layer, the charge storage layer including at least one first crystal including a first region having one space group selected from a group consisting of a space group Pca21 (space group number 29), a space group R3 (space group number 146), a space group R3m (space group number 160), and a space group Pmn21 (space group number 31), and the charge storage layer containing oxygen (O), at least one first element selected from a group consisting of hafnium (Hf) and zirconium (Zr), and at least one second element selected from a group consisting of titanium (Ti), cerium (Ce), tantalum (Ta), tungsten (W), niobium (Nb), molybdenum (Mo), manganese (Mn), ruthenium (Ru), and tin (Sn).

13. The semiconductor memory device according to claim 12,
wherein the at least one first crystal further includes a second region having one space group selected from a group consisting of a space group P42/nmc (space group number 137), a space group Pbca (space group number 61), and a space group Pbcm (space group number 57).

14. The semiconductor memory device according to claim 12,
wherein the at least one first crystal further includes a third region different from the first region and having one space group selected from a group consisting of a space group Pca21 (space group number 29), a space group R3 (space group number 146), a space group R3m (space group number 160), and a space group Pmn21 (space group number 31).

15. The semiconductor memory device according to claim 12,
wherein the charge storage layer further contains at least one third element selected from a group consisting of barium (Ba), strontium (Sr), and calcium (Ca).

16. The semiconductor memory device according to claim 12,
wherein the charge storage layer further contains at least one fourth element selected from a group consisting of aluminum (Al) and silicon (Si).

17. The semiconductor memory device according to claim 12,
wherein a median of a long diameter of the at least one first crystal is equal to or more than 1 nm and equal to or less than 5 nm.

18. The semiconductor memory device according to claim 12,
wherein a median of a long diameter of the at least one first crystal is equal to or less than half a thickness of the charge storage layer.

19. The semiconductor memory device according to claim 12,
wherein the charge storage layer includes a matrix region surrounding the at least one first crystal.

20. The semiconductor memory device according to claim 19,
wherein the matrix region is amorphous.

21. The semiconductor memory device according to claim 19,
wherein the matrix region contains the second element, and
an atomic concentration of the second element in the first crystal is lower than an atomic concentration of the second element in the matrix region.

22. The semiconductor memory device according to claim 12,
wherein each of the at least one first crystal includes a plurality of polarization domains, and
a median of the number of the plurality of polarization domains included in each of the at least one first crystal is equal to or more than 3 and equal to or less than 100.
